(19) United States
(12) Patent Application Publication
(10) Pub. No.: US 2015/0040819 A1
(43) Pub. Date: Feb. 12, 2015

(54) SYSTEM AND METHOD FOR FORMING A SILICON WAFER

(71) Applicant: Energy Materials Research, LLC, Holly, MI (US)

(72) Inventor: Carl E. Bleil, Rochester Hills, MI (US)

(73) Assignee: Energy Materials Research, LLC, Holly, MI (US)

(21) Appl. No.: 13/961,960

(22) Filed: Aug. 8, 2013

(51) Int. Cl. C30B 15/06; C30B 15/14

(52) U.S. Cl. CPC C30B 15/06; C30B 15/14
USPC 117/27; 117/212

(57) ABSTRACT

An apparatus for forming a crystalline ribbon from molten silicon having a silicon ribbon support. A heater is provided including a pair of spaced planar electrodes parallel to the surface of the molten silicon for capacitively coupling radio frequency electrical currents into the material causing a ribbon of material to melt along a zone. A conductive electrode in thermal contact with a respective cooler and a dielectric layer between the conductive and semi-conductive electrodes is provided. A controller configured to control the removal of heat from the melted ribbon of material in a direction substantially perpendicular to the surface of the molten silicon to effect crystal growth.

### FIELD

The present disclosure relates to a system and method to form a crystal and, more particularly, to a system and method to form a silicon crystal ribbon.

### BACKGROUND

This section provides background information related to the present disclosure that is not necessarily prior art. There is a need for thin crystalline ribbons and films of many materials such as silicon and other semiconductors. These ribbons are often very costly and difficult to produce. For example, thin wafers of monocrystalline semiconductor materials are generally produced from monocrystalline boules grown by the Czochralski technique. The preparation of the thin wafers from large single crystal boules requires slicing and polishing, is a costly and time consuming technique, and inherently wastes much of the single crystal unprocessed material. Consequently, much effort has been directed toward growing thin monocrystalline ribbons that need only be scribed and broken to be used. Crystal ribbons have been grown from a melt in a crucible where a heater is positioned below the melt surface, a heat sink is positioned above the melt surface, and the ribbon is pulled horizontally from the surface of the melt. This technique produces single crystal ribbons much faster than the previous methods. However, pulling a ribbon too quickly or at too great an angle from horizontal introduces grain boundaries and imperfections that degrade the performance of circuitry placed on the semiconductor surface. Further, crystal ribbon width has been limited, thus decreasing the usefulness of the ribbons. Moreover, the necessary controls to implement the process and produce very thin crystal ribbons and films of good quality are difficult to manage and thus the commercial advantage is reduced.

While ribbon growth has been demonstrated for a given material using the techniques disclosed in the prior art, it has become apparent that improvements in the control of the process would lead to more reliable operation, extension to other materials, wide ribbons and a better product. For example, there is a tendency for dendritic structures to form in the created ribbons. It has been suggested that a low axial temperature gradient in the ribbon is necessary to prevent dendritic growth.

### SUMMARY

This section provides a general summary of the disclosure, and is not a comprehensive disclosure of its full scope or all of its features. It is, therefore, an object of the teachings to provide a method and apparatus for improved temperature control and fluid flow in the growth of crystalline ribbon from a source of liquid material.

The apparatus for forming a crystalline ribbon from source material has first and second heating electrodes associated with a crucible configured to hold molten silicon. The crucible has a formation portion having a flange member that supports and holds liquid silicon between the flange and the crystalline ribbon. The flange comprises a textured surface configured to hold liquid silicon and reduce turbulence of liquid silicon flowing over the surface.

The teachings are carried out in a method of growing a crystal ribbon from source material having the steps of electrically heating a body of liquid source material to form and maintain a ribbon floating on molten source material, the ribbon has surfaces coplanar with the desired crystal film via electrodes which are displaced from the film and the molten source material, heating the source material by selectively applying a radiofrequency signal to the source material, cooling the other surface of the film to effect ribbon growth wherein the combined heating and cooling steps control the temperature gradient in the film normal to an angled film growth surface, and moving the ribbon on the liquid surface in an axial direction away from the liquid source molten film as the film grows.

The teachings are further carried out by apparatus for forming a crystalline ribbon from source material having a film of material that floats on a liquid material surface in a plane, a first heater having a pair of RF electrodes spaced apart from the film in capacitive conductive relation to the film, and a controller for controlling the electrodes to maintain the liquid at a temperature just above the melting point of the material. The controller regulates initially heating the material and subsequently stabilizing the temperature of a liquid surface adjacent the film liquid growth interface. A second heater melts and maintains the temperature of the source of material. The first heater includes a planar electrode parallel to the ribbon plane for capacitively coupling radio frequency electrical currents into the liquid material, causing a film of material to melt along a solid-liquid interface zone incorporated in the source body.

According to alternate teachings, a controller is provided which uses a transmitted RF energy to liquid silicon below a mono-crystalline ribbon. A cooler having an angled reflective surface is provided for removing heat from the surface of the liquid silicon in a direction substantially perpendicular to the plane, to effect ribbon growth and form a crystalline film of material. An actuator causes relative motion to the crystal ribbon parallel to a plane between the ribbon and the heater.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 represents a side sectional view of an apparatus for forming a silicon ribbon according to the present teachings;

FIG. 2 represents a top view of the apparatus shown in FIG. 1 with the RF heater removed;

FIG. 3 represents a top view of the apparatus shown in FIG. 2 with the crucible and the RF heater removed;

FIGS. 4a and 4b represent top and side views of a crucible with liquid silicon according to the present teachings;

FIGS. 5a and 5b represent top and side views of a crucible according to the present teachings; and

FIG. 6 represents a perspective view of the crucible shown in FIGS. 5a and 5b.

Corresponding reference numerals indicate corresponding parts throughout the several views of the drawings.

### DETAILED DESCRIPTION

While the description below is directed to a development for growing mono-crystalline ribbons of silicon, it will be recognized that it applies, with suitable modification, to other materials such as germanium and bismuth. For such materials, the molten state of the substance has substantially higher electrical conductivity than the solid state, and the surface tension between the liquid and solid is adequate to sustain a short unsupported molten zone.

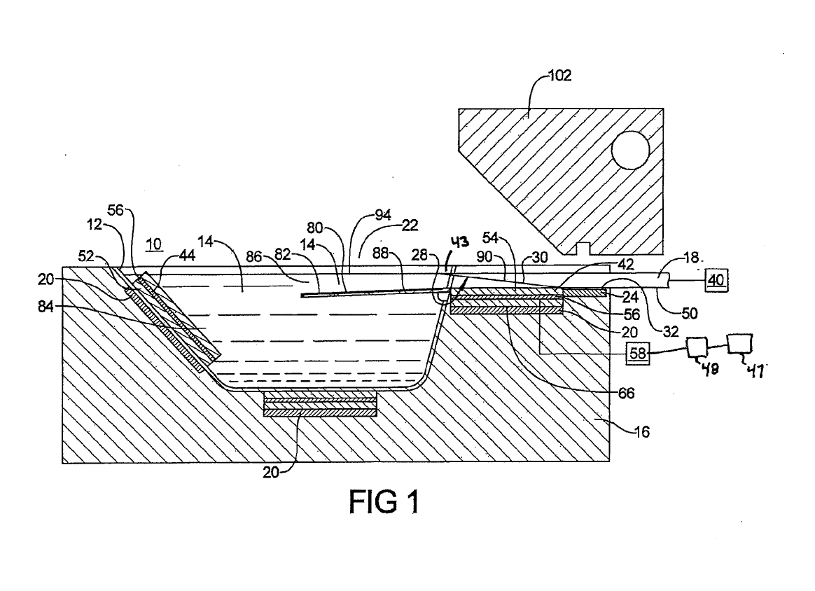

A cross section of the apparatus 10 for forming a mono-crystal ribbon is shown in FIG. 1. The apparatus 10 provides a crucible 12 for holding molten silicon 14 and a support structure 16 that supports the crucible 12 and a plurality of associated heaters 20. As further described below, a mono-crystal 18 is formed at a location generally at the melt level in the crucible 12. The mono-crystal 18 floats on the surface of the molten silicon 14 and is slowly drawn off of the molten silicon 14 while it grows to form a uniform mono-crystalline ribbon 18.

The mono-crystal 18 is placed on support 32, and has an upper surface that lies in a horizontal plane. A silicon wedge 30 of the mono-crystal 18 and wedge of liquid material 28 lays directly over a formation portion 22 of the crucible 12 with the nucleating tip 94 of mono-crystal 18 over the flange and having a thick end of the wedge adjacent the RF electrode 42. This wedge 30 represents the mono-crystal formation front for the crystal 18 that floats on the surface of the molten silicon 14 and is supported by wafer support 32. The mono-crystal 18 is electrically insulated from the wafer support 32 by layer 24 of material such as boron nitride, which provides thermal conduction between the silicon sheet and the supporting associated heaters.

The apparatus 10 for forming a crystalline ribbon from source material has first and second heating electrodes 42, 44 and the plurality of heaters 16 associated with a crucible 12 configured to hold molten silicon. The crucible 12 has a formation portion 22, having a flange member 80 that supports and holds liquid silicon between the flange 80 and the mono-crystal 18. The flange 80 comprises a textured surface 82 configured to hold liquid silicon and reduce turbulence of liquid silicon flowing over the surface.

Formation of the mono-crystal 18 is initiated by a process where a seed of mono-crystalline material is positioned on the surface of molten silicon above the formation portion 22 and allowed to grow. A pulling mechanism 40 attached to the seed crystal is controlled to move the ribbon away from the nucleating tip 94 position and off the molten silicon. Similarly, when processing other materials, the use of like material for the supports or other elements is advantageous, although silicon may be used for processing materials of lower melting points.

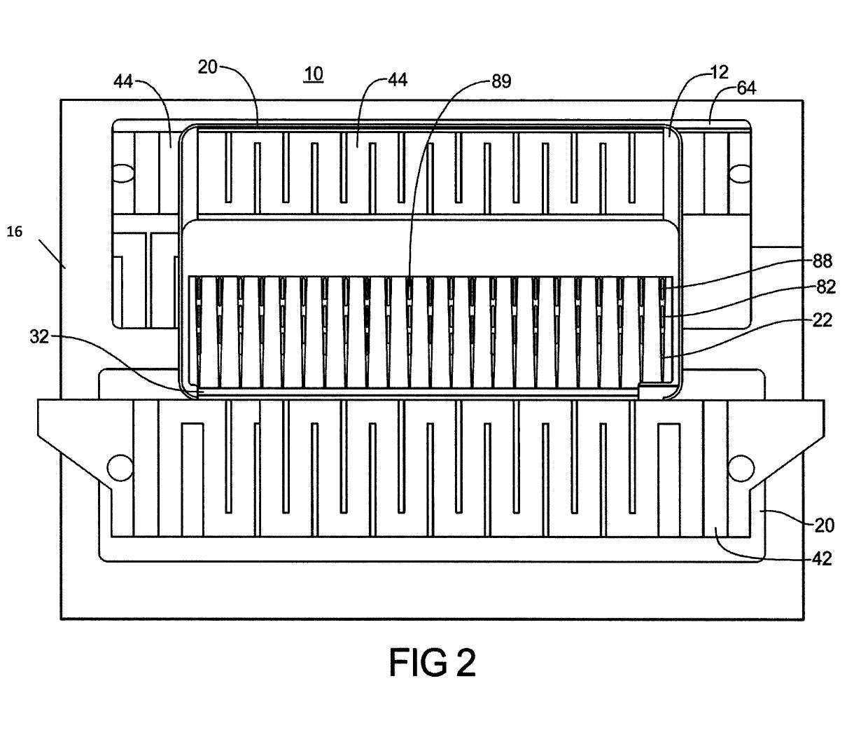

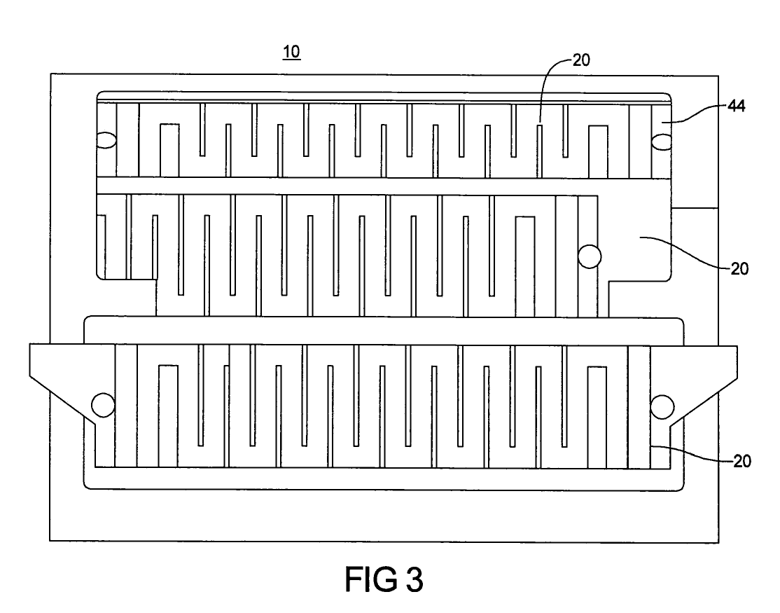

As best seen in FIGS. 1-3, beneath the mono-crystal 18 film of source material is one of a pair of spaced primary laminar ensemble electrodes 42 and 44. Electrode 44 is situated generally on either side of the wedge of liquid 28. The first electrode 42 is parallel to the mono-crystal 18 and is spaced apart from a lower surface 50 and wedge 30 of the mono-crystal 18. The second electrode may be angled with respect to the lower surface 50 of the mono-crystal 18 and is capacitively coupled to the first electrode 42. The electrodes 42, 44 are separated from the molten silicon by a layer material such as boron nitride.

The electrodes 44 have a lower plate of a material such as boronnitide, a central plate 54 of a metal such as molybedenum, and an upper dielectric layer 56 such as silicon nitride for capactively coupling. The central plate 54 is connected to a terminal of a radio frequency voltage source 58. The electrode 42 has a similar structure and its upper electrode is connected to another terminal of voltage source 58. Thus, the pair of electrodes 42, 44 couple RF energy into the film mono-crystal 18 for resistance heating of the wedge of liquid material 28 immediately adjacent to the silicon wedge 30. In this regard, the electrodes 42, 44 are configured to provide the heat of fusion necessary to maintain the tip of the wedge 30 in a liquid state during processing. Because of the nature of the electronic circuit between the plates 42, 44, the current varies from one side of the wedge 30 to the tip, with the amount of current being increased along the distance of the wedge 30 to the tip. In this regard, the RF source is driven in a manner that the effective strength of the field changes the current along the length of the wedge 30. By adjusting the field using a controller (not shown), the position of the forming edge of the single crystal at the wedge 30/liquid wedge 28 interface can be modified.

A heater 20 is mounted below the electrode 42 and thermally coupled to and electrically isolated from the electrode 42 by a layer 66 of material, such as boron nitride. This heater functions to maintain the mono-crystal 18 at a temperature at or just below its melting point. The rate of in-flow of replenishment material can be controlled by the RF power so the flow is consistent with the rate of ribbon growth maintaining the location of the wedge 30/liquid wedge 28 interface.

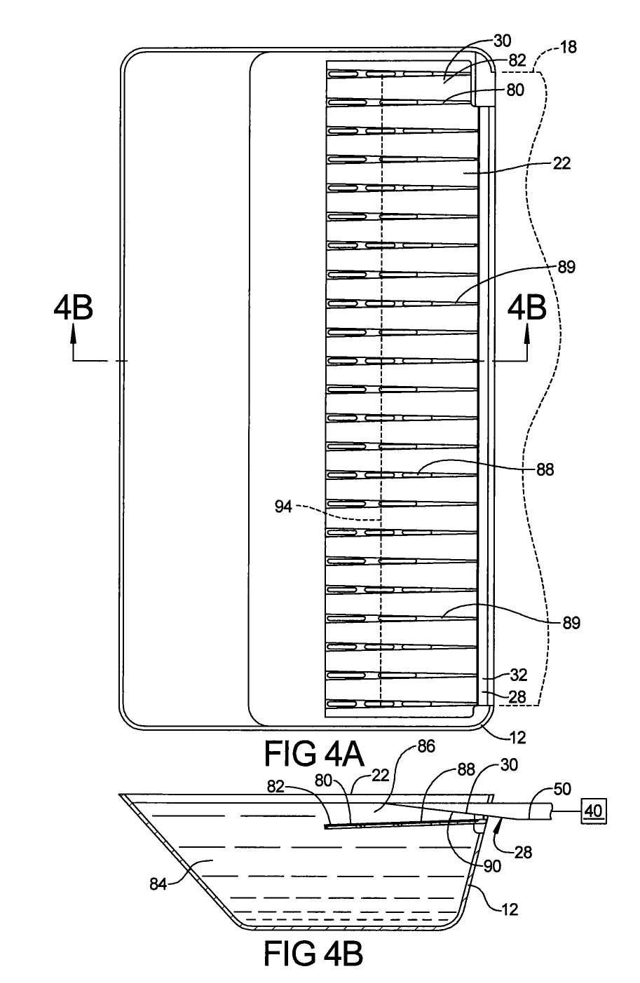

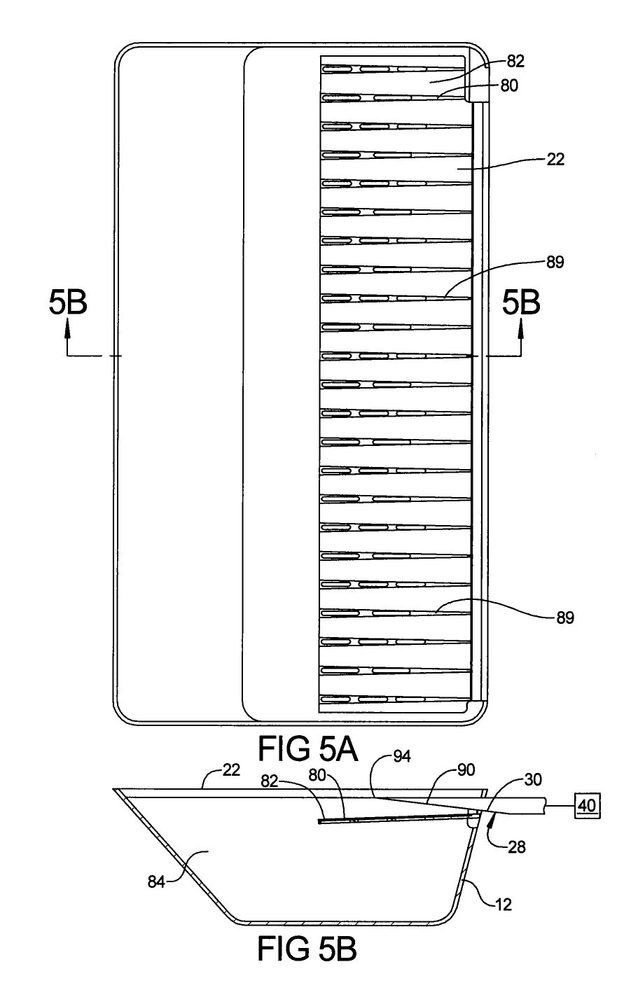

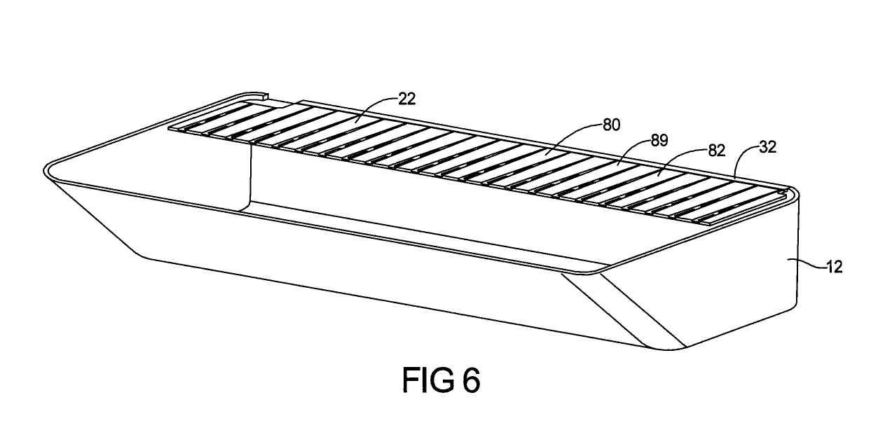

Another embodiment is expressed in FIGS. 4a-6 wherein the formation portion 22 of the crucible 12 is shown. FIGS. 4a and 4b represent top and side views of a crucible with liquid silicon and floating mono-crystal 18, according to the present teachings. FIGS. 5a and 5b represent top and side views of a crucible according to the present teachings having the liquid silicon removed. The formation portion 22 has a flange member 80 that supports and holds the liquid silicon being selectively heated by the first set of electrodes 42, 44. The flange member 80 has a surface 82 that generally faces the lower surface of the mono-crystal 18. This slightly angled surface is texturized so as to allow the full wetting of the surface 82 with the molten silicon. Formed on the surface 82 can be a plurality of through holes 88 that fluidly couple liquid silicon from the pool of liquid silicon 84 with liquid silicon 86 disposed between the surface 82 and the mono-crystal 18. It is envisioned that the texturization and through holes 88 can also be formed on the surface of a portion immediately adjacent to the wedge 30. As seen, the texture can be associated with grooves 89 formed in the surface 82. It should be noted that due to the surface tension of the liquid silicon 84, flow through the through holes 88 is constrained or restricted.

The texturization and through holes 88 are configured to allow the turbulent free flow of the liquid silicon over the surface 82, thus allowing improved formation of the mono-crystal 18. In this regard, as the crystal is slowly withdrawn out of the heated zone, the current from the electrodes 42, 44 allows the formation of the wedge 30 into a planar mono-crystal member generally perpendicular to the wedge 30/liquid wedge 28 interface. Fluid is constantly being replenished from the pool of liquid silicon into the liquid silicon 86 disposed between the surface 82 and the mono-crystal 18. The texturization and through holes 88 provide a liquid surface of material for the incoming silicon to flow over the flange surface 82, thus reducing turbulent flow. It should be noted the texturization need not provide a source of liquid silicon to the space between the surface 82 and the mono-crystal 18.

The heaters 20 may be constructed and operated in accordance with known principles as set forth in the two part paper, Asselman and Green, Heat Pipes, Philips tech Rev. 33, 104-113. 1973 (No. 4) and Philips tech Rev. 33, 138-148, 1973 (No. 5) with the added feature of using the isothermal body as an auxiliary heat source or heat sink. The active working fluid is preferably bismuth or lithium and may be combined with an inactive gas such as argon. The application of the heaters or coolers to the ribbon growing process takes advantage of the high-speed convective ability of the coolers to maintain a uniform temperature along its length and maintain a constant temperature for varying heat flux. The particular temperatures to be used depend on several parameters such as the type and amount of material between the ribbon or melt and the heat sink and the rate of crystal growth.

The operation is initiated by placing on the fluid surface a film of seed material having the desired crystal orientation. The electrodes 20 are heated to 1400° C. to bring the temperature of the seed material to 1400°, and then the electrodes 42 or 44 are energized by RF or DC current to further raise the ribbon temperature to 1405°. The melt zone 90 is established by then applying the RF energy to the electrodes 42 and 44 to bring the selected portion of the ribbon up to the melting point, 1410°, due to resistance heating by the current flow through the liquid silicon. The cooler 102, which has an angled reflective surface, maintains the cooling mode to remove heat from the growing ribbon. The angled reflective surface, which is angled at an angle greater than about 45°, has a surface reflective to infrared light. When stabilized, thermal gradient will remain uniform from the highest melt temperature at the electrode 44 to the lowest crystal temperature at the heat sink 102. After stability has been attained, the crystal growth mode is entered by pulling the ribbon and maintaining the temperature gradient throughout the growth zone of ribbon. The heat of fusion that mist be provided to the growth zone and extracted from the growing crystal depends on the volume of the ribbon and the rate of growth determines the rate of heat extraction.

Throughout the steady state operation, two conditions are desired. First, the interface of the electrodes 42, and the melt 14 is an isothermal plane maintained just above the melting point of the silicon source material. A second heat flux from the solid melt interface 30 determines the rate of solidification is controlled in accordance with the volume rate of ribbon growth.

Steady state operation occurs after the system stabilizes upon start-up. The melting of the replenishing pool is begun and is regulated to match the ribbon growth to replenish the melt. The pulling mechanism 40 advances the ribbon as soon as the molten replenishing material enters the melt zone. The ribbon growth occurs essentially perpendicular to the wedge 30/liquid 38 interface, and the ribbon is pulled axially. This allows fast pulling speed at a low crystal growth rate because growth is taking place over a large surface area and growth is substantially perpendicular to the pulling direction.

Each heater 20 serves as a heat clamp, providing a constant and uniform temperature substantially unaffected by variations in heat flux. A uniform heat flux between the heaters and the plane to be controlled is maintained by continuous thermal sensing so that isothermal planes can be established. For example, the heating electrode 42 and the boron nitride layer 46 between the heater and the top surface of the mono-crystal 18 afford a single valued temperature gradients so that the electrode/melt interface has a uniform temperature.

The capacitive characteristic of the electrodes 42, 44 assures a variable current density is passed from the electrodes 42, 44 into the material being melted so that the whole width of the mono-crystal 18 is subject to variable heating. The RF impedance of the silicon nitride dielectric layer of electrode plates 42, 44 permits the plates to serve as a capacitor yet the relatively high DC resistance at 1400 degrees centigrade discourages lateral current flow in the plates that might increase current to film regions offering a lower path of resistance. Current flow in the formed sheet is inhibited by the resistivity of the silicon mono-crystal 18 which is higher than that of liquid silicon wedge 28. Because of the variable heating current density and the uniform surrounding temperature controlled by the heaters 20, the thermal gradients are uniform across the melt zone and wide ribbons can be produced.

The nucleating tip 94 of the wedge 30 is maintained within the formation portion 22 above the surface 82 to prevent or reduce the formation of dendrites or other crystalline structures that would convert the mono-crystal into poly-crystal. The heat removal from the wedge 30 and liquid wedge 28 is sufficient to cause freezing at the melt interface to thereby cause ribbon growth. The shape of the melt zone is determined in part by properties of capacitive coupling and by the difference in electrical conductivity between the solid and liquid states of the silicon: the liquid conductivity is 30 times greater than the solid conductivity. As a result, the current prefers to flow in the liquid and the interface 96 between the liquid silicon and the ribbon wedge 30 can be sharply controlled. After the melt profile is established, only low power is required to maintain the melt zone. The growth interface is inherently stable because the liquid electrical and thermal conductivities are much larger than the solid and small changes in melt thickness will alter the resistance to return the interface to its stable position. During the crystal formation, impurities are rejected by the crystal and tend to concentrate in the liquid between the flange and the mono-crystal 18. However, the melt below the growing ribbon is moving with the ribbon as it grows. The flow of the melt exceeds the diffusion rate of the impurities in opposition of the flow which leads to the effective capture of the impurities in the ribbon as it exits the growth zone.

The high electrical conductivity ratio for silicon results in a wedge 30 angle of only about 2°. The flange member 80 below the mono-crystal 18 is provided with a similar but negative angle to the wedge 30. The thickness of silicon across the width of the ribbon wedge 30, and the mono-crystal 18 will be the same along the region of crystal growth. Thus, the shape and position of the melt zone is determined and the electrodes 42 and 44 are positioned accordingly. Because of crystallization kinematics, contaminants or deposits within the melt are rejected during the crystal formation. Because of this, there is an increased amount of contaminant in the wedge shaped melt 28. When drawn, and finally hardened, these contaminants can plate onto a surface of the crystal.

The first and second heater electrodes 42, 44 capacitively couple electrical energy to the mono-crystal 18. Each planar electrode 42, 44 comprises an electrode that produces a which passes through the molten silicon and has a supporting heater to provide a uniform base temperature and having a cooler or heat sink held at a constant temperature to provide for crystal growth. The cooler can have a heat source at one end, a heat sink at the other end and a main body having a constant uniform temperature gradient, and the main body is in thermally conductive relation to the ribbon, and wherein the heat source and the heat sink each comprise a constant temperature bath including a partially molten material having a melting point at the said constant temperature. A controller (not shown) coupled to a cooler is provided for removing heat from the crystalline ribbon of material in a direction substantially perpendicular to the plane of the ribbon to effect ribbon growth.

To form the silicon ribbon from a crystalline ribbon source, the system floats a silicon crystal on a bed of molten silicon. The temperature of the crystal silicon is brought to the melting point of the silicon material, the system floats a silicon crystal on a bed of molten silicon. The silicon crystal is heated with a first heater, electrode 42 having a plate defined along the silicon for initially heating a portion of the material and subsequently stabilizing the temperature surrounding the silicon crystal. The temperature of the molten silicon is maintained with a second heater for melting the liquid silicon material. Selected radio frequency electrical currents at between in the range of 1 to 10 megahertz pursuant to the relationship X=(2/ωμσ)^{0.5} ln(I₀/I);

where x=the desired ribbon thickness ω the frequency μ is the permeability of free space and σ is the conductivity are capacitively coupled into the material causing a portion of the silicon crystal, depending on the frequency selected, to melt along a wedge-shaped zone. Heat from the melted silicon crystal of material is removed in a direction substantially perpendicular to the plane to effect silicon crystal growth.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. As used herein, the phrase at least one of A, B, and C should be construed to mean a logical (A or B or C), using a non-exclusive logical OR. It should be understood that one or more steps within a method might be executed in different order (or concurrently) without altering the principles of the present disclosure.

In this application, including the definitions below, the term controller may be replaced with the term circuit. The term module may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term code, as used above, may include software, firmware, and/or microcode, and may refer to programs, routines, functions, classes, and/or objects. The term-shared processor encompasses a single processor that executes some or all code from multiple modules. The term group processor encompasses a processor that, in combination with additional processors, executes some or all code from one or more modules. The term-shared memory encompasses a single memory that stores some or all code from multiple modules. The term group memory encompasses a memory that, in combination with additional memories, stores some or all code from one or more modules. The term memory may be a subset of the term computer-readable medium. The term computer-readable medium does not encompass transitory electrical and electromagnetic signals propagating through a medium, and may, therefore, be considered tangible and non-transitory. Non-limiting examples of a non-transitory tangible computer readable medium include nonvolatile memory, volatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. An apparatus for forming a crystalline ribbon from a source of molten silicon comprising:
first and second heating electrodes;
a crucible configured to hold molten silicon, having a surface of the molten silicon, the crucible having a formation portion, said formation portion having a flange member that supports and holds the molten silicon between the flange member and the crystalline ribbon, the flange member being angled with respect to the surface of the molten silicon and defining a surface texture configured to hold molten silicon and reduce turbulence of the molten silicon flowing over the surface texture, the molten silicon being heated by the first and second heating electrodes;
the first heating electrode positioned below the surface of the molten silicon, comprising a temperature regulator in thermally conductive relation to the ribbon configured to melt a wedge portion of the crystalline ribbon to form a growth zone and subsequently stabilize the temperature surrounding the wedge portion of the crystalline ribbon;
the second heating electrode positioned below surface of the molten silicon, configured to maintain the temperature of the molten silicon, wherein second electrode is in capacitively conductive relation with both the first heating electrode and the molten silicon through the molten silicon from the first heating electrode past the crystalline ribbon;
a controller configured to control application of RF energy to the molten silicon by the first and second heating electrodes; and
a pulling mechanism configured to cause relative motion of the crystalline ribbon parallel to the first heating electrode.

2. The apparatus as defined in claim 1, wherein the first and second heating electrodes capacitively couple electrical energy to the ribbon and each heating electrode comprises an electrode that produces a current distribution in contact with the molten silicon.

3. The apparatus as defined in claim 1, wherein the first heating electrode is positioned adjacent a cooler having a heat sink maintained at a constant temperature.

4. The apparatus as defined in claim 2, wherein the first heating electrode produces a varying electronic current through the molten silicon.

5. The apparatus as defined in claim 1, wherein the flange member defines a plurality of through apertures.

6. (canceled)

7. An apparatus for forming a crystalline ribbon of molten silicon comprising:
a crucible configured to hold molten silicon, the crucible having a formation portion, said formation portion having a textured flange member that supports and holds molten silicon between the flange and a portion of the crystalline ribbon floating on the molten silicon;
a first heater electrode comprising a plate positioned adjacent to the ribbon in thermally conductive relation to the source material and means for controlling a temperature just above a melting point of the molten silicon for initially heating the material and subsequently stabilizing the temperature adjacent to the ribbon at a melt solid interface;
a second heater for melting the molten silicon material configured to maintain the temperature of the molten silicon at its melting temperature, including a pair of spaced planar electrodes capacitively coupling radio frequency electrical currents into the molten silicon and imparting a heat of fusion to the molten silicon to a ribbon tip location causing a portion of the ribbon of material to melt along a zone;
a controller configured to control the removal of heat from molten silicon material in a direction substantially perpendicular to the surface of the molten silicon to effect crystal growth; and
a mechanism for causing relative motion parallel to a plane between the ribbon and the heater.

8. The apparatus as defined in claim 7, further comprising a cooler configured to remove heat from the crystalline ribbon.

9. The apparatus as defined in claim 8, wherein each cooler comprises a heat sink having a constant uniform temperature.

10. The apparatus as defined in claim 7, wherein the cooler comprises a surface angled with respect to the crystalline ribbon, the surface being reflective at infra-red frequencies.

11. A method of forming a crystalline ribbon from molten silicon comprising:
floating a silicon crystal on a surface of a bed of molten silicon;
heating the silicon crystal with a first heater comprising a plate defined along the silicon crystal in capacitive conductive relation to the silicon crystal;
controlling a temperature of the molten silicon to a temperature at a melting point of molten silicon for initially heating the material and subsequently stabilizing the temperature surrounding the silicon crystal;
maintaining the temperature of the molten silicon with a second heater for melting the molten silicon material;
capacitively coupling radio frequency electrical currents into the molten silicon causing a portion of the silicon crystal to melt along a zone; and
removing heat from the silicon crystal in a direction substantially perpendicular to the surface of the liquid silicon to effect silicon crystal growth of the silicon crystal; and
causing relative motion parallel to the surface of the molten silicon between the ribbon and the heater.

12. The method as defined in claim 11, wherein removing heat from the silicon crystal comprises controlling a temperature below a melting point of the material and in thermally conductive relation to a side of the ribbon.

13. The method as defined in claim 11, comprising providing a layer of molten silicon between a textured flange and the silicon crystal.

14. The method as defined in claim 13, wherein capacitively coupling radio frequency electrical currents into the molten silicon causes a portion of the silicon crystal to melt along a zone capacitively coupling radio frequency electrical currents into the layer of molten silicon.

15. The method as defined in claim 13, further comprising capacitively coupling radio frequency electrical currents into a source of molten silicon.

16. An apparatus for drawing a crystalline ribbon from molten silicon comprising:
a crucible configured to hold the molten silicon, the crucible having a formation portion, said formation portion having a textured flange member defining a plurality of molten silicon holding cavities, wherein the flange member supports and holds a moving portion of the molten silicon between the flange and the crystalline ribbon;
a first heater electrode positioned below the surface of the molten silicon and a distance from the moving portion of the molten silicon in capacitive conductive relation to the moving portion of the molten silicon and having a controller configured to control a temperature just above a melting point of the moving portion of the molten silicon and to initially heat the moving portion of the molten silicon and subsequently stabilize the temperature surrounding a wedge portion of the crystalline ribbon, said wedge portion being below the surface of the molten silicon;
a second heater electrode displaced from and non-parallel to the first heater electrode, positioned a distance from the moving portion of the molten silicon in capacitive conductive relation to the moving portion of the molten silicon and the first heater electrode, the second heater electrode configured to impart a heat of fusion to the moving portion of the molten silicon along and at a ribbon tip causing a ribbon of material to melt along a zone;
the controller configured to control application of RF energy to the moving portion of the molten silicon by the first and second electrodes; and
a pulling mechanism configured to cause relative motion of the crystalline ribbon parallel to the surface of the molten silicon between the ribbon and the first heater electrode.

17. The apparatus as defined in claim 16, wherein the holding cavities define a plurality of through apertures to fluidly couple the moving portion of the molten silicon to a source of molten silicon, and increase laminar flow of the liquid silicon.

18. (canceled)

19. The apparatus as defined in claim 16, wherein the application of RF energy is the application of RF energy to the moving portion of the molten silicon.

20. The apparatus as defined in claim 16, wherein the application of RF energy is the application of RF energy at between about 10 to 20 Mhz.
